(19) United States
(12) Patent Application Publication
(10) Pub. No.: US 2009/0261905 A1
(43) Pub. Date: Oct. 22, 2009

(54) OPEN GAIN ADJUSTMENT CIRCUIT FOR OPERATIONAL AMPLIFIER

(75) Inventor: Kazuhisa Ishiguro, Gunma (JP)

Correspondence Address: CONNOLLY BOVE LODGE & HUTZ LLP, 1875 EYE STREET, N.W., SUITE 1100, WASHINGTON, DC, 20006, US

(73) Assignees: NIIGATA SEIMITSU CO., LTD., Jyoetsu-shi (JP); RICOH CO., LTD., Tokyo (JP)

(21) Appl. No.: 12/091,294

(22) PCT Filed: Jul. 12, 2006
(86) PCT No.: PCT/JP2006/314199

§ 371 Date: Apr. 23, 2008

(30) Foreign Application Priority Data
Oct. 24, 2005 (JP) 2005-308016

(51) Int. Cl. H03G 3/00

(52) U.S. Cl. 330/278

(57) ABSTRACT

An operational amplifier comprises: a differential amplifier circuit (11) that performs a differential amplification operation based on the difference of signals received at two input terminals (IN1, IN2); and a source-grounded amplifier (M5) connected to an output of the differential amplifier circuit (11). In the operational amplifier, there are provided a bias resistor (Rb) connected to the gate of the source-grounded amplifier (M5) and a bias circuit (M20) connected to the bias resistor (Rb). The gate bias of the source-grounded amplifier (M5) is supplied from the bias circuit (M20) through the bias resistor (Rb) so that the input resistance of the source-grounded amplifier (M5) is determined by the bias resistor (Rb) and the input resistance of the source-grounded amplifier (M5) can be reduced.

### TECHNICAL FIELD

The present invention relates to an open gain adjustment circuit for an operational amplifier; and, in particular, the present invention is suited to be used in an open gain adjustment circuit for a type of operational amplifier for extracting the output of a differential amplifier circuit at the input stage using a source-grounded amplifier at the subsequent stage.

### BACKGROUND ART

Power amplifiers include class A, class AB, class B, class C, and class D amplifiers depending on differences of operating points. Class A and class AB amplifiers are often used for audios and “class AB push-pull types” are often employed in which the upper half portion (positive half-period) and the lower half portion (negative half-period) of an alternating signal are operated by respective transistors to realize low current consumption. In the class AB push-pull type, an output signal is generated by driving the upper half portion and the lower half portion by an output transistor with a push-pull connection.

FIG. 1 is a diagram showing an exemplary configuration of an operational amplifier using a conventional class A operation. In FIG. 1, reference numeral 11 denotes a differential amplifier circuit comprising: a differential pair made of two transistors M1 and M2; a current mirror circuit made of two transistors M3 and M4 for receiving an output of the differential amplifier circuit 11 with double ends; and a constant current circuit Ic connected to the differential pair. The pair of transistors M1 and M2 of the differential pair has their gates connected to two input terminals IN1 and IN2.

Additionally, sources of the two transistors M1 and M2 are connected each other and one end of the constant current circuit Ic is connected to their common source. The other end of the constant current circuit Ic is grounded. Drains of the two transistors M1 and M2 are connected to a power supply VDD through the respective transistors M3 and M4. The transistors M3 and M4 are connected each other by a current mirror.

Reference characters R1 and R2 denote bias resistances applying a bias voltage VB to the transistors M1 and M2. Additionally, reference character M5 denotes a source-grounded transistor whose gate is supplied with an output signal of the differential amplifier circuit 11, and which functions as a source-grounded amplifier. The source-grounded amplifier M5 has its drain connected to a constant current circuit Io and an output terminal OUT, while a source of the source-grounded amplifier M5 is connected to the power supply VDD. In this manner, the conventional class A amplifier receives the output of the differential amplifier circuit 11 by the source-grounded amplifier M5 (refer, for example, to Patent Document 1).

[Patent Document 1] Japanese Patent Laid-Open No. 2005-215897

### DISCLOSURE OF THE INVENTION

However, under the conventional technology as mentioned in FIG. 1, the input resistance of the source-grounded amplifier M5 becomes high, resulting in increasing the open gain of the operational amplifier. In some cases depending on the kind and usage of an application circuit for applying the operational amplifier, the open gain of the operational amplifier is required to decrease. In such a case, there was a problem that the conventional circuit configuration as shown in FIG. 1 could not be used.

The present invention has been made to solve such a problem, and the purpose of the present invention is to make it possible to decrease the open gain of the operational amplifier.

In order to solve the problem as mentioned above, an open gain adjustment circuit for an operational amplifier according to the present invention is applied to an operational amplifier comprising: a differential amplifier circuit to perform differential amplification operation based on the difference of signals inputted from two input terminals and a source-grounded amplifier connected to the output of the differential amplifier circuit; and comprises a bias resistor connected to the gate of the source-grounded amplifier and a bias circuit connected to the bias resistor.

According to the present invention configured as mentioned above, the gate bias of the source-grounded amplifier is supplied from the bias circuit through a bias resistor. With this, the input resistance of the source-grounded amplifier is determined by the bias resistance. Owing to the presence of such a bias resistor, the input resistance of the source-grounded amplifier can be decreased, thereby enabling decrease of the open gain of the operational amplifier.

### BRIEF DESCRIPTION OF THE DRAWINGS

FIG. 1 shows the configuration of a conventional operational amplifier; and

FIG. 2 shows an example of the configuration of an operational amplifier to which an open gain adjustment circuit according to the present invention is applied.

### BEST MODE FOR CARRYING OUT THE INVENTION

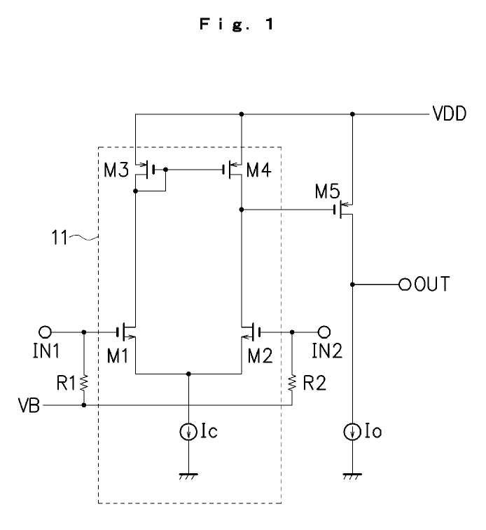

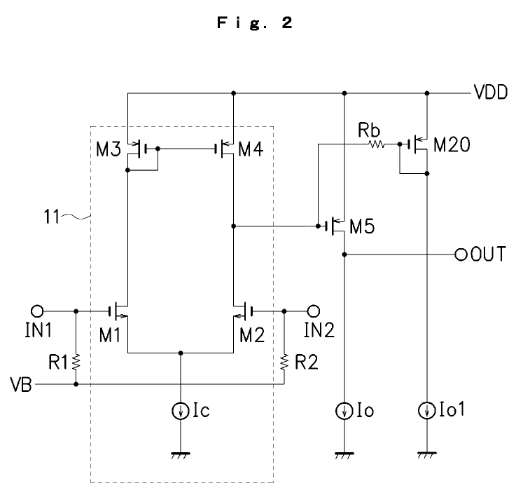

Hereinafter, one embodiment of the present invention will be described with reference to the drawings. FIG. 2 shows an example of the configuration of an operational amplifier to which an open gain adjustment circuit according to the present invention is applied. The operational amplifier of the present embodiment is formed by CMOS processes. In addition, in FIG. 2, the same reference numeral is assigned for a component having the same function as that of the corresponding component shown in FIG. 1.

As shown in FIG. 2, the operational amplifier of the present embodiment has a configuration to extract the output of a differential amplifier circuit 11 by means of a source-grounded amplifier M5. The differential amplifier circuit 11 comprises a differential pair consisting of two transistors M1 and M2, current mirror circuits M3 and M4 for extracting the output of the differential amplifier circuit 11 with double ends, and a constant current circuit Ic connected to the differential pair.

The gate of the source-grounded amplifier M5 is connected to the output of the differential amplifier circuit 11, and the source of the source-grounded amplifier M5 is connected to a power supply VDD. In addition, the drain of the source-grounded amplifier M5 is connected to the constant current circuit Io, and it is also connected to an output terminal OUT.

In the present embodiment, furthermore, a bias resistor Rb is connected to the gate of the source-grounded amplifier M5. In addition, a transistor M20 is connected between the power supply VDD and a constant current circuit Io1. The transistor M20, whose gate and drain are connected, functions as a bias circuit. The drain of the transistor M20 is connected to the constant current circuit Io1. The bias resistor Rb is connected to the gate of the transistor M20.

As mentioned above, in the present embodiment, the gate bias of the source-grounded amplifier M5 is supplied from the transistor M20 (bias circuit), whose gate and drain are connected, through the bias resistor Rb. When the present embodiment is configured as mentioned above, the input resistance (the load resistance of the differential amplifier circuit 11) of the source-grounded amplifier M5 is determined by the resistance of the bias resistor Rb. With this, by setting the resistance of the bias resistor Rb to an appropriate value, the input resistance of the source-grounded amplifier M5 can be decreased, thereby enabling decrease of the open gain of the operational amplifier.

In addition, the drain current of the source-grounded amplifier M5 is determined by the drain current of the transistor M20. Because the transistors M5 and M20 are configured as current mirror circuits, if the sizes of the transistors M5 and M20 are made equal, the drain currents flowing through these circuits are made equal.

In addition, in the embodiment mentioned above, the bias resistor Rb may be a variable resistor. While the embodiment mentioned above represents only a specific example for practicing the present invention, it is to be understood that the technical scope of the present invention is not limited thereto. That is to say, the present invention can be implemented in various form without departing from the spirit and scope of the present invention.

### INDUSTRIAL APPLICABILITY

An open gain adjustment circuit according to the present invention is useful for a type of operational amplifier for extracting the output of a differential amplifier circuit at the input stage using a source-grounded amplifier at the subsequent stage.

1. An open gain adjustment circuit applied to an operational amplifier comprising a differential amplifier circuit to perform differential amplification operation based on the difference of signals inputted from two input terminals and a source-grounded amplifier connected to the output of the differential amplifier circuit, characterized by comprising:
a bias resistor connected to the gate of the source-grounded amplifier; and
a bias circuit connected to the bias resistor.

2. The open gain adjustment circuit for the operational amplifier according to claim 1, characterized in that the bias circuit comprises a transistor whose gate and drain are connected and the bias resistor is connected to the gate of the transistor.

3. The open gain adjustment circuit for the operational amplifier according to claim 2, characterized in that the transistor size of the source-grounded amplifier and the transistor size of the bias circuit are made equal.
